(19) United States
(12) Patent Application Publication
(10) Pub. No.: US 2024/0072787 A1
(43) Pub. Date: Feb. 29, 2024

(54) OUTPUT DRIVING CIRCUIT AND SYSTEM INCLUDING THE SAME

(71) Applicant: Haechitech Corporation, Cheongju-si (KR)

(72) Inventors: Tae Woo OH, Bucheon-si (KR); Sung Keun LEE, Yongin-si (KR)

(73) Assignee: Haechitech Corporation, Cheongju-si (KR)

(21) Appl. No.: 18/105,063

(22) Filed: Feb. 2, 2023

(30) Foreign Application Priority Data
Aug. 29, 2022 (KR) 10-2022-0108198

(51) Int. Cl. H03K 17/082; H03K 5/24

(52) U.S. Cl. CPC H03K 17/082; H03K 5/24

(57) ABSTRACT

Disclosed are a circuit and a system which is capable of improving reliability by preventing destructive overvoltage that occurs in an element using a low power supply voltage when various signals are transmitted from an integrated circuit with a high power supply voltage to an integrated circuit with a low power supply voltage.

### CROSS-REFERENCE TO RELATED APPLICATION

The present application claims priority of Korean Patent Application No. 10-2022-0108198 filed on Aug. 29, 2022, the entire contents of which are incorporated herein for all purposes by this reference.

### BACKGROUND OF THE DISCLOSURE

### Field of the Disclosure

The present disclosure relates to an output driving circuit and a system including the same, and is directed to preventing the decrease of reliability of an element due to a difference in voltage that occurs when data is transmitted between multiple ICs using different power supply voltages.

### DESCRIPTION OF THE RELATED ART

Integrated circuits (ICs) in a system using the multiple ICs often use different power supply voltages. For example, as illustrated in FIG. 1, when two integrated circuits IC1 and IC2 use power supply voltages of V_{DDL} and V_{DDH} respectively, and a value of V,_{DDL} is 1.2 V and the value of V_{DDH} is 1.8 V, a HIGH value of data SDA transmitted from IC2 to IC1 becomes 1.8 V. In this case, IC2 transmits the HIGH voltage of 1.8 V of V_{DDH} to a gate of an input terminal transistor while the operating voltage of a transistor in an internal circuit of IC1 is 1.2 V, which causes a problem of destroying the dielectric of a gate oxide film. In particular, even though the power supply voltage is the HIGH value of 1.8 V, it is only a standard or intermediate value, and the maximum value allowed in the commercial specification is often more than 10% greater than 1.8 V. Therefore, the problems described above may be getting more serious. In addition, in an electronic circuit system that includes multiple ICs, particularly, in case that IC1 is a host CPU and IC2 is an IC capable of inputting/outputting serial data, the difference in power supply voltages may often cause the above-described problem.

### SUMMARY OF THE DISCLOSURE

The present disclosure has been made in an effort to provide a circuit and a system including the same which is capable of preventing an overload of voltage received by input terminal elements of IC1 to prevent elements from being destroyed, and further preventing malfunctions, by sensing an interface voltage when a signal is transmitted from an IC with a high power supply voltage to an IC with a low power supply voltage.

According to one aspect, there is provided an output driving circuit including: a step-down circuit unit configured to sense an input voltage and reduce a sensed input voltage; a plurality of switch units; a step-up circuit unit; a voltage regulation unit; an output unit; and a control unit.

According to another aspect, there is provided a system including: a first integrated circuit IC1 configured to use a first power supply voltage; and a second integrated circuit IC2 configured to use a second power supply voltage and comprising an output driving circuit, in which the output driving circuit may include a step-down circuit unit configured to sense and reduce an input voltage, a plurality of switch units, a step-up circuit unit, a voltage regulation unit, an output unit, and a control unit.

According to an embodiment of the present disclosure, there is an advantage in that a load due to the overvoltage is reduced to prevent elements from being destroyed and prevent malfunction by sensing an interface voltage and transmitting an appropriate output voltage when a signal is transmitted from an IC with a high power supply voltage to an IC with a low power supply voltage.

### BRIEF DESCRIPTION OF THE DRAWINGS

FIG. 1 is a conceptual view for schematic explanation of the present disclosure.

FIG. 2 is a block diagram illustrating an embodiment according to the present disclosure.

FIG. 3 is a table illustrating a mode selection according to the present disclosure.

FIG. 4 is a view illustrating the embodiment according to the present disclosure.

FIG. 5 is a view illustrating an overall circuit according to the present disclosure.

FIG. 6 is a circuit diagram illustrating an operation of an input mode.

FIG. 7 is a circuit diagram illustrating an operation of an open-drain mode among output modes.

FIG. 8 is a circuit diagram illustrating an operation of a push-pull mode among the output modes.

FIG. 9 is a circuit diagram illustrating another operation of the push-pull mode among the output modes.

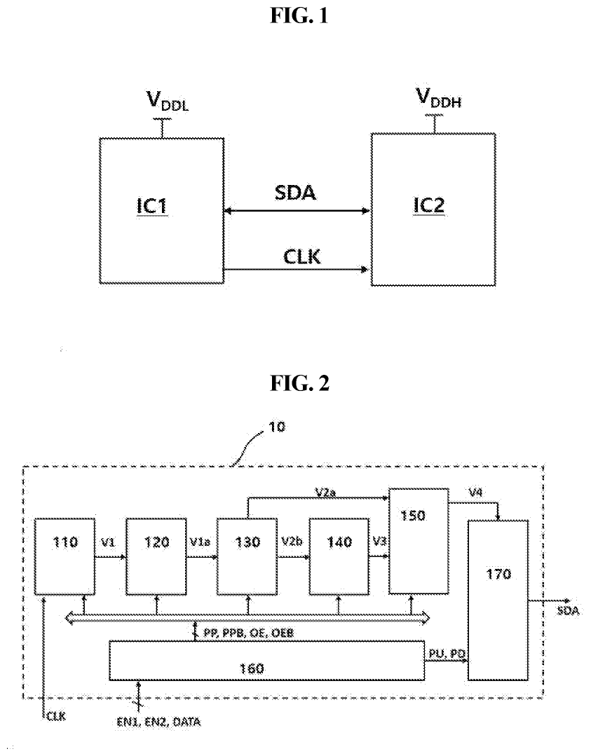

### DETAILED DESCRIPTION OF THE DISCLOSURE

Hereinafter, embodiments of the present disclosure will be described in detail with reference to the accompanying drawings so that those with ordinary skill in the art to which the present disclosure pertains may easily carry out the embodiments. The same reference numerals refer to the same members among the reference numerals indicated in the respective drawings.

In the description of the present disclosure, the specific descriptions of publicly known related technologies will be omitted when it is determined that the specific descriptions may obscure the subject matter of the present disclosure.

The terms such as “first” and “second” may be used to describe various constituent elements, but the constituent elements should not be limited by the terms, and these terms are used only to distinguish one constituent element from another constituent element.

In addition, the terms representing the voltage node or current flow represent the values of voltage and current and may be used interchangeably.

To solve the above-mentioned problems, an output driving circuit according to the present disclosure may be applied to an output terminal of an IC connected to a relatively high power supply voltage and may be operated in various modes depending on conditions. FIG. 2 is a block diagram illustrating an output driving circuit according to an embodiment of the present disclosure. Referring to FIG. 2, a schematic configuration of the present disclosure will be described. An output driving circuit 10 may be constituted to include a step-down circuit unit 110, a first switch unit 120, a step-up circuit unit 130, a second switch unit 140, a voltage regulation unit 150, a control unit 160, and an output unit 170.

Inputs of the output driving circuit 10 of the present disclosure include a clock signal CLK, signals EN1 and EN2 for controlling an output mode of the control unit 160, a data input signal DATA and the like, and an output data signal of the output driving circuit 10 is SDA. The control unit 160 generates a push-pull control signal PP, pull-up and pull-down control signals PU and PD, and an output enable signal OE. For reference, throughout the specification of the present disclosure, inverted signals of the signals PP and OE are denoted as PPB and OEB, respectively. In addition, the output SDA is denoted as an abbreviation for ‘Serial Data’ which also means data transmitted/received serially, however, throughout the specification of the present disclosure, the output SDA is only used to avoid confusion with the data input signal DATA for convenience and it should be noted that the meaning of the term is not intended to limit the scope of the present disclosure. Therefore, the present disclosure may be of course applied to all types of data transmission as well as circuits and systems for serial data transmission.

The clock signal CLK, the signals EN1 and EN2 for controlling the output mode of the control unit 160, the data input signal DATA, and the like may be generated inside a host CPU such as an IC1 and then transmitted to an integrated circuit including the output driving circuit 10 of the present disclosure, such as an IC2, and may also be properly generated inside the IC2 depending on the demands of a system designer. A HIGH voltage value of the above-mentioned signals may be a low power supply voltage, V_{DDL}, for example, 1.2 V, when generated inside the IC1, and may be a high power supply voltage, V_{DDH}, for example, 1.8 V, when generated inside the IC2. In particularly, the signals EN1 and EN2 for controlling the output mode may be generated by combining appropriate logic circuits within the host CPU such as the IC1.

The step-down circuit unit 110 reduces a voltage VH of the clock signal CLK in HIGH state by a threshold voltage of a transistor and then outputs a reduced voltage as an output voltage V1. Of course, the voltage VH may be either the high power supply voltage V_{DDH} or the low power supply voltage V_{DDL} in some cases, however, in this case, the voltage VH is V_{DDL}, and a voltage VL in LOW state which the clock signal CLK has is equal to a ground voltage VSS.

The first switch unit 120 transmits a voltage V1 through appropriate control and outputs an output voltage V1a. The step-up circuit unit 130 adds twice the threshold voltage of the transistor to the voltage V1a through appropriate control and outputs an output voltage V2b. In this case, in the step-up circuit unit 130, a well-known voltage bootstrapping circuit in two stages may be used.

The second switch unit 140 serves to transmit the V2b input voltage to an output voltage V3 through appropriate control and the voltage regulation unit 150 serves to supply an appropriate voltage to a power supply voltage V4 of the output unit 170 according to each operation mode through a comparator within the voltage regulation unit 150.

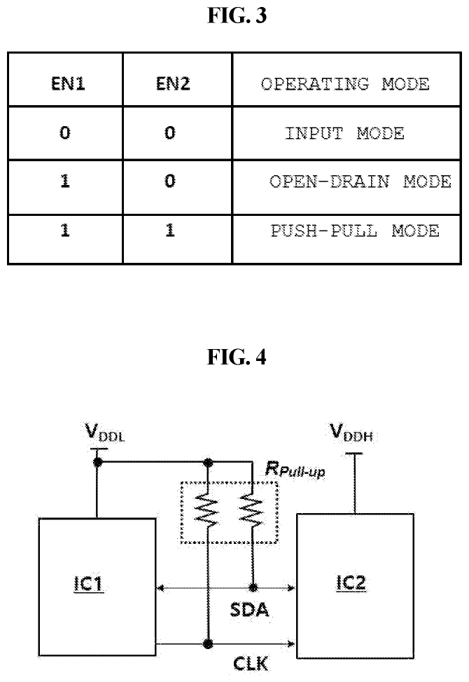

The control unit 160 generates the remaining control signals, that is, the push-pull control signal PP and the inverted signal PPB of the push-pull control signal PP, the pull-up and pull-down control signals PU and PD, the output enable signal OE and the inverted signal OEB of the output enable signal OE so that an appropriate output mode is set by the logic states of the output mode control signals EN1 and EN2. The output mode control signals and the remaining control signals determine the output mode by controlling the operations of the step-down circuit unit 110, the first switch unit 120, the step-up circuit unit 130, the second switch unit 140, the voltage regulation unit 150, the control unit 160, and the output unit 170. FIG. 3 illustrates a case in that the operation modes set when the logical combinations of (EN1 and EN2) are (0,0), (1,0), and (1,1) are an input mode, an open-drain mode, and a push-pull mode, respectively. It should be noted that one of the essential spirits of the present disclosure is not that the three operation modes are fixedly unchanged according to the state of the specific logical combination of (EN1, EN2), for example, the state of (1,1) is fixed to the push-pull mode, but that the three operating modes are selectively determined by the logical combinations of the output control signals.

In the present disclosure, an SDA output node is bidirectional to be responsible for both transmission and reception so that the timings of transmission and reception are distinct from each other and are used for the SDA node to receive data in the input mode. Therefore, the output driving circuit of the present disclosure is controlled not to transmit any signal.

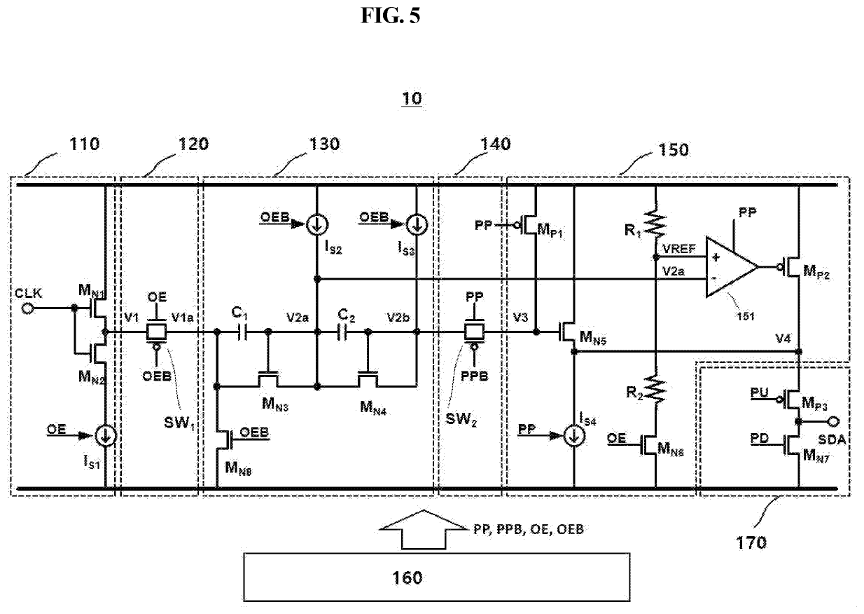

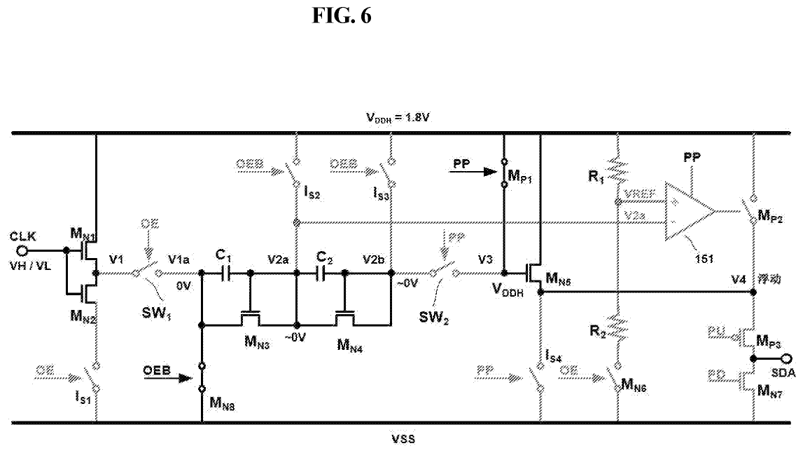

The open-drain mode is a type of output mode in which the circuit of the present disclosure transmits the data SDA to the outside. In this case, a pull-down element in the output unit 170 is responsible for data ‘LOW’, but a separate pull-up resistor Rₚᵤₗₗ₋ᵤₚ connected to the outside of the IC2 is responsible for data ‘HIGH’ as illustrated in FIG. 4.

The push-pull mode is also a type of output mode in which the data SDA is transmitted to the outside. In this case, a pull-up element and the pull-down element in the output unit 170 are responsible for both date ‘LOW’ and data ‘HIGH’.

Hereinafter, the detailed operation of an embodiment of a circuit for each block will be described with reference to the circuits and timing diagrams illustrated in FIGS. 5 to 9. FIG. 5 is view illustrating the embodiment of circuits for blocks other than the control unit 170, and FIG. 6 is a view for explaining the operations of the circuits of FIG. 5 in the input mode. For reference, the state in which current does not flow through each element that is turned-off is represented in gray, and current sources or transistors may also be represented by switches for convenience.

In case that the input mode, that is, the (EN1, EN2) signal is (0, 0), the high power supply voltage V_{DDH} is connected to each block, and a switch I_{S1} of the step-down circuit unit 110 and switches SW₁ and SW₂ of the first and second switch units 120 and 140 are turned off. Therefore, the clock signal CLK is not transmitted to the next stage even though the clock signal CLK is input. C₁, M_{N3} and C₂, M_{N4} which constitute two bootstrap stages of the step-up circuit unit 130 also do not perform bootstrapping operations. A comparator 151 in the voltage regulation unit 150, and a pull-up element M_{P3} and a pull-down element M_{N7} of the output unit 170 are also all turned off. Therefore, the output node SDA floats and is not affected by the output driving circuit of the present disclosure, and as a result, the transmitting function of the bidirectional function of the output node SDA to be responsible for transmission and reception is stopped so as not to interfere with receiving data.

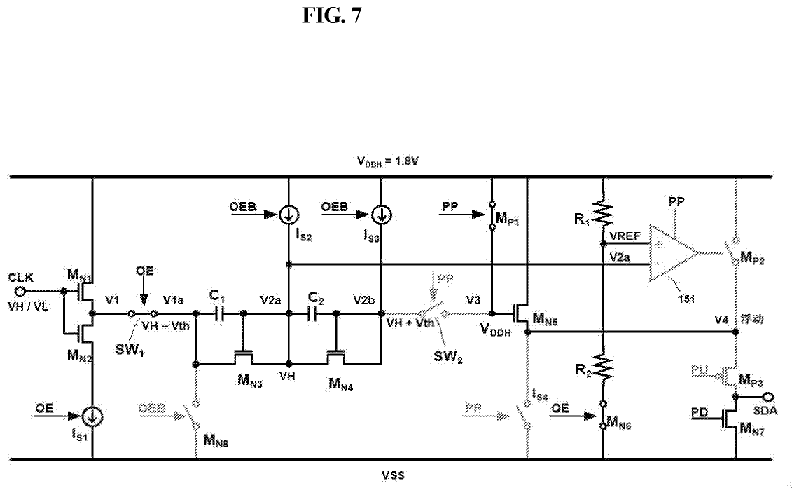

FIG. 7 illustrates a circuit diagram in case that the circuit of the present disclosure is operated as the open-drain mode in which the (EN1, EN2) signal is (1, 0) among the output modes. The switch I_{S1} of the step-down circuit unit 110 is turned on and the switches SW₁ and SW₂ of the first and second switch units 120 and 140 are turned on and turned off, respectively, and thus the clock signal CLK is transmitted to the next stage when the clock signal CLK is input. In this case, it should be noted that the HIGH signal VH is transmitted after the voltage thereof is reduced by a threshold voltage Vth since a transistor M_{N1} is an NMOS transistor. That is, a voltage of VH-Vth is transmitted. For example, when VH is 1.8 V which is V_{DDH} and the threshold voltage Vth is 0.6 V, a HIGH voltage of 1.2 V is transmitted.

Two switches I_{S2} and I_{S3} of the step-up circuit unit 130 are turned on by the OE and OEB signals, and C₁, M_{N3} and C₂, M_{N4} which constitute the two bootstrap stages also start the bootstrapping operations. Therefore, in case that the clock signal CLK is HIGH, the output voltage V1 of the step-down circuit unit 110 becomes VH-Vth, and output voltages V2a and V2b of the bootstrap stages are increased again by Vth to become VH and VH+Vth, respectively.

Since the switch SW₂ of the second switch unit 140 is turned off, only V2a, which is an output of a first stage of the output voltages V2a and V2b of the bootstrap stages, is transmitted as an input to the comparator of the voltage regulation unit 150 and V2b, which is an output of a second stage, is not transmitted to other circuits.

Although a transistor M_{N6} in the voltage regulation unit 150 is turned on, the operation of the comparator 151 is being stopped by the enable signal PP, and the pull-up element M_{P3} of the output unit 170 is also turned off by a pull-up signal PU into which the input signal DATA is logically transformed through the control unit 160. Therefore, an output V4 of the voltage regulation unit 150 floats during the pull-up operation, and the output voltage node SDA is charged by the pull-up resistor as illustrated in FIG. 4.

When the input signal DATA is LOW, the output node SDA is discharged through the transistor M_{N7} by the pull-down signal PD which is logically transformed through the control unit 160.

In summary of the above descriptions, when the input signal DATA is HIGH, the output node SDA is charged with the same value as the power supply voltage connected to the pull-up resistor by the current through the pull-up resistor, and when the input signal DATA is LOW, the data signal is transmitted to the output signal SDA by discharging through a discharge path of the circuit of the present disclosure.

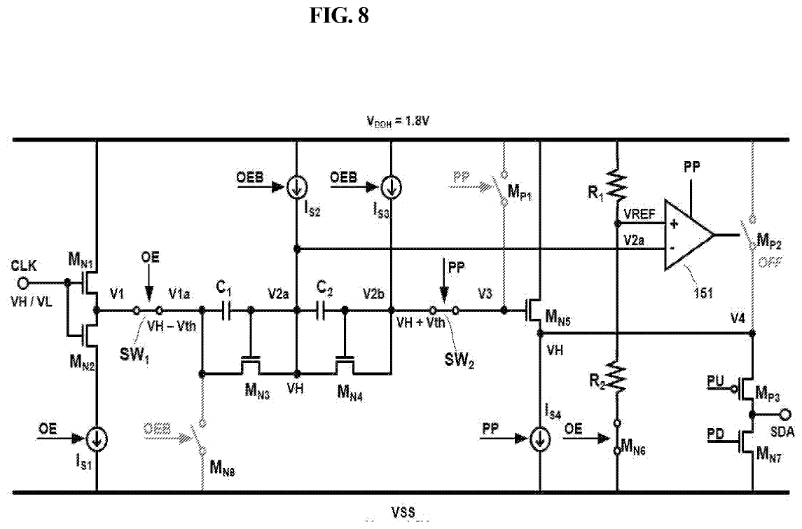

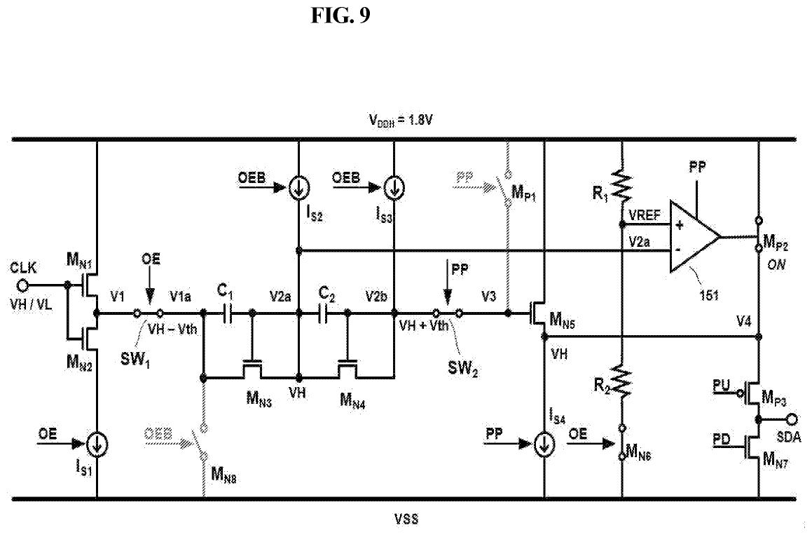

In case that the circuit of the present disclosure is operated as the push-pull mode in which the (EN1, EN2) signal is (1, 1) among the output modes, the operation of the circuit varies depending on whether the HIGH voltage VH of the clock signal CLK is equal to V_{DDL} (e.g., 1.2 V) or V_{DDH} (e.g., 1.8 V). Hereinafter, the operation of the circuit will be described with reference to FIGS. 8 and 9 that illustrate the operation of the circuit in each case.

First, when the HIGH voltage of the clock signal CLK is the low power supply voltage V_{DDL}, for example 1.2 V, the operation of the circuit illustrated in FIG. 8 is performed. In this output mode, the transistors and switches connected to the OE signal corresponding to the output enable signal and the inverted signal OEB of the OE signal are all turned on. Therefore, the other transistors and switches except M_{N8} of the step-up circuit unit 130, and M_{P1} and M_{P2} of the voltage regulation unit 150 are turned on.

In particular, of the two inputs of the voltage regulation unit 150, a voltage of non-inverting input connected to a reference voltage VREF is a value divided from the voltage of V_{DDH} by resistors R₁ and R₂, and has a value between V_{DDH} and V_{DDL}. Of the two inputs of the voltage regulation unit 150, the voltage V2a of an inverting input terminal is connected to the first bootstrap stage of the step-up circuit unit 130, and thus has the VH voltage, that is, the value of V_{DDL}. Therefore, in this case, since the non-inverting input is dominant in the comparator 151 of the voltage regulating unit 150, the output of the comparator 151 is saturated in a positive (+) direction toward the power supply voltage, V_{DDH}, and M_{P2} is turned off.

The clock signal CLK is transmitted to M_{N8} which is a source follower element of the voltage regulating unit 150 via the step-down circuit unit 110, the first switch unit 120, the step-up circuit unit 130, and the second switch unit 140, and subsequently, the VH voltage is supplied to the power supply voltage of the pull-up element, M_{P3} of the output unit 170 by the operation of the source follower element, M_{N8}.

Of course, the pull-up element M_{P3} and the pull-down element M_{N7} of the output unit 170 are alternately turned on by the PU and PD signals into which the data input signal DATA is logically transformed by the control unit 160. Finally, the output signal SDA is capable of swinging between the low power supply voltage V_{DDL} and the ground voltage VSS, and thus the voltage value of HIGH becomes, for example, 1.2 V.

Next, a case in which the HIGH voltage VH of the clock signal CLK in the output push-pull mode is equal to the high power supply voltage V_{DDH}, for example 1.8 V will be described with reference to FIG. 9. This case is the same as the operation of the push-pull mode described above except for the operation of the voltage regulation unit 150. However, of the two inputs of the voltage regulation unit 150, the voltage V2a of the inverting input terminal is connected to the first bootstrap stage of the step-up circuit unit 130 and has the VH voltage, that is, V_{DDH}, and thus the voltage V2a exceeds a reference voltage of the inverting input terminal. Therefore, since the inverting input is dominant in the comparator 151 of the voltage regulating unit 150, the output of the comparator 151 is saturated in a negative (−) direction toward the ground voltage, which turns on M_{P2}, which is PMOS. Thus, the V_{DDH} voltage is supplied to the power supply voltage of the pull-up element M_{P3} of the output unit 170.

In summary of the above descriptions, the pull-up element M_{P3} and the pull-down element M_{N7} of the output unit 170 are alternately turned on by the PU and PD signals into which the data input signal DATA is logically transformed by the control unit 160. Finally, the output signal SDA is capable of swinging between the high power supply voltage V_{DDH} and the ground voltage VSS, and thus the circuit of the present disclosure may transmit the data voltage value of HIGH, for example, 1.8 V.

While the present disclosure has been described with reference to the embodiments illustrated in the drawings, the embodiments are for illustrative purposes only, and those skilled in the art to which the present disclosure pertains will understand that various modifications of the embodiment and any other embodiment equivalent thereto are available. Accordingly, the true technical protection scope of the present disclosure should be determined by the technical spirit of the appended claims.

What is claimed is:

1. An output driving circuit comprising:
a step-down circuit unit configured to sense an input voltage and reduce a sensed input voltage;
a plurality of switch units;
a step-up circuit unit;
a voltage regulation unit;
an output unit; and
a control unit.

2. The output driving circuit of claim 1, wherein one of the plurality of switch units is disposed forward of the step-up circuit unit, and another switch unit is disposed rearward of the step-up circuit unit.

3. The output driving circuit of claim 1, wherein a voltage bootstrapping operation of the step-up circuit unit is performed two or more times.

4. The output driving circuit of claim 1, wherein the voltage regulation unit comprises a comparator.

5. The output driving circuit of claim 1, wherein the voltage regulation unit comprises a source follower element.

6. The output driving circuit of claim 1, wherein the control unit generates signals for selecting input/output modes.

7. The output driving circuit of claim 6, wherein a mode selected from the input/output modes is one of an input mode, an open-drain output mode, and a push-pull output mode.

8. The output driving circuit of claim 1, wherein the output unit comprises a pull-up element and a pull-down element that is operated so that an output data signal is transmitted by a pull-up signal and a pull-down signal corresponding to an input data signal.

9. The output driving circuit of claim 7, wherein in the push-pull output mode, a saturation voltage of a comparator is selectively changeable according to a voltage range of an input data signal or a clock signal.

10. A system comprising:
a first integrated circuit IC1 configured to use a first power supply voltage; and
a second integrated circuit IC2 configured to use a second power supply voltage and comprising an output driver circuit,
wherein the output driver circuit comprises:
a step-down circuit configured to sense and reduce an input voltage;
a plurality of switch units;
a step-up circuit unit;
a voltage regulation unit;
an output unit; and
a control unit.

11. The system of claim 10, wherein one of the plurality of switch units is disposed forward of the step-up circuit unit, and another switch unit is disposed rearward of the step-up circuit unit.

12. The system of claim 10, wherein a voltage bootstrapping operation of the step-up circuit unit is performed two or more times.

13. The system of claim 10, wherein the voltage regulation unit comprises a comparator.

14. The system of claim 10, wherein the voltage regulation unit comprises a source follower element.

15. The system of claim 10, wherein the control unit generates signals for selecting enable input/output modes.

16. The system of claim 15, wherein a mode selected from the input/output modes is one of an input mode, an open-drain output mode, and a push-pull output mode.

17. The system of claim 10, wherein the output unit comprises a pull-up element and a pull-down element that are operated so that an output data signal is transmitted by a pull-up signal and a pull-down signal corresponding to an input data signal.

18. The system of claim 16, wherein in the push-pull output mode, a saturation voltage of a comparator is selectively changeable according to a voltage range of an input data signal or a clock signal.

19. The system of claim 10, wherein the second power supply voltage is higher than the first power supply voltage.

20. The system of claim 13, wherein one input of input terminals of the comparator is a reference voltage generated by a voltage divider of a power supply voltage.
